(19) United States
(12) Patent Application Publication
(10) Pub. No.: US 2006/0141154 A1
(43) Pub. Date: Jun. 29, 2006

(54) Method for treating the surface of a part made of a heat-structured composite material and use thereof in brazing parts made of a heat-structured composite material

(76) Inventor: Jacques Thebault, 33200 Bordeaux (FR)

Correspondence Address: WEINGARTEN, SCHURGIN, GAGNEBIN & LEBOVICI LLP, TEN POST OFFICE SQUARE, BOSTON, MA, 02109, US

(21) Appl. No.: 10/543,363

(22) PCT Filed: Jan. 29, 2004
(86) PCT No.: PCT/FR04/00202

§ 371 Date: Jul. 26, 2005

(30) Foreign Application Priority Data
Jan. 30, 2003 (FR) 0301039

(51) Int. Cl. C23C 16/00

(52) U.S. Cl. 427/249.2

(57) ABSTRACT

A liquid composition is applied onto the surface of the part to be treated, the composition containing a ceramic precursor polymer and a refractory solid filler. After cross-linking, the polymer is transformed into ceramic by heat treatment, and subsequently ceramic is deposited by chemical vapor infiltration. Before the chemical vapor infiltration step, the surface of the part is shaved so as to return the composite part to its initial shape so that the chemical vapor infiltration forms a deposit that fills in the residual micropores in the shaved surface of the part.

### BACKGROUND OF THE INVENTION

Thermostructural composite materials are known for their good mechanical properties and their ability to conserve these properties at high temperature. They comprise carbon/carbon (C/C) composite materials made of carbon fiber reinforcement densified by a carbon matrix, and ceramic matrix composite (CMC) materials made of refractory fiber reinforcement (carbon fibers or ceramic fibers) densified by a matrix that is ceramic, at least in part. Examples of CMCs are C/SiC composites (carbon fiber reinforcement and silicon carbide matrix), C/C—SiC composites (carbon fiber reinforcement and matrix comprising a carbon phase, generally next to the fibers, and a silicon carbide phase), and SiC/SiC composites (fibers and reinforcement both made of silicon carbide). An inter-phase layer may be interposed between the reinforcing fibers and the matrix in order to improve the mechanical strength of the material.

The usual methods of obtaining parts made of thermo-structural composite material are the liquid method and the gas method.

The liquid method consists in making a fiber preform having substantially the shape of the part that is to be made, and that is to constitute the reinforcement of the composite material, and in impregnating said preform with a liquid composition containing a precursor for the matrix material. The precursor is generally in the form of a polymer, such as a resin, possibly diluted in a solvent. The precursor is transformed into ceramic by heat treatment, after eliminating any solvent and cross-linking the polymer. A plurality of successive impregnation cycles may be performed in order to reach the desired degree of densification. By way of example, liquid precursors of carbon can be resins having a relatively high coke content, such as phenolic resins, whereas liquids that are precursors of ceramic, in particular of Si, can be resins of the polycarbosilane (PCS) type or the polytitano-carbosilane (PTCS) type.

The gas method consists in chemical vapor infiltration (CVI). The fiber preform corresponding to a part to be made is placed in an oven into which a reaction gas mixture is admitted. The pressure and the temperature that exist in the oven and the composition of the gas are selected in such a manner as to enable the gas to diffuse within the pores of the preform so as to form the matrix therein by depositing a solid material on the fibers, which material is the result either of a component of the gas decomposing or else of a reaction between a plurality of components. By way of example, gaseous precursors of carbon can be hydrocarbons such as methane and/or propane giving carbon by cracking, and a gaseous precursor of ceramic, in particular of SiC, may be methyltrichlorosilane (MTS) that gives SiC by the MTS decomposing.

Because of their properties, thermostructural composite materials find applications in a variety of fields for making parts that are to be subjected to high levels of thermomechanical stress, e.g. in the fields of aviation and space.

Nevertheless, the fact that thermostructural composite materials inevitably present some degree of porosity and present a rough appearance can lead to limitations as to possible uses.

The porosity comes from the inevitably incomplete nature of the densification of fiber preforms. It means that pores of greater or smaller dimensions are present and communicate with one another. As a result, parts made of thermostructural composite material are not leakproof, which means they cannot be used raw for making walls that are cooled by fluid circulation, e.g. wall elements of a rocket thruster nozzle or wall elements of gas turbine combustion chambers, or indeed wall elements of a plasma confinement chamber in a nuclear fusion reactor.

The rough surface appearance is due to the presence of surface irregularities. These prevent the desired degree of geometrical precision being achieved when the parts are to be assembled together by brazing in order to build up a part of more complex shape.

Surface treatments for parts made of thermostructural composite material are known, essentially for the purpose of improving their ability to withstand an oxidizing atmosphere. The idea is to plug the surface pores of the material so as to avoid the material being degraded by oxidation of the carbon which may be present in the fiber reinforcement or in the matrix, or of the carbon or the boron nitride which may be present at an inter-phase between fibers and matrix.

Amongst the numerous known treatments for providing protection against oxidation, document WO 92/19567 proposes applying a liquid composition on the surface of the part to be protected, the composition containing a ceramic precursor polymer and a ceramic powder, cross-linking the polymer, transforming the ceramic precursor polymer by heat treatment, and then forming a deposit of ceramic by chemical vapor infiltration.

Such a method is not suitable when the surface state of a composite material part needs to be inspected and to comply with dimensional tolerances, in particular when the initial shape of the part needs to be complied with. This is important when the part is to be assembled with one or more other parts, or when it needs to present a precise surface shape, e.g. having a mirror appearance.

### OBJECT AND SUMMARY OF THE INVENTION

An object of the invention is to provide a method that does not present the above-mentioned drawback, and that can be used for obtaining parts made of thermostructural composite material with a surface state that is mastered, in particular a surface that is leakproof or a surface of smooth appearance that satisfies dimensional precision requirements.

This object is achieved with a method of treating the surface of a part made of thermostructural composite material possessing a surface that is porous and of rough appearance, the method comprising applying onto the surface of the part a liquid composition containing a ceramic precursor polymer and a refractory solid filler, cross-linking the polymer, transforming the cross-linked polymer into ceramic by heat treatment, and subsequently forming a ceramic deposit by chemical vapor infiltration, in which method, in accordance with the invention, prior to the step of chemical vapor infiltration, the surface of the part is shaved to return the part made of composite material to its initial shape so that the chemical vapor infiltration forms a deposit that fills in the residual micropores in the shaved surface of the part.

Thus, by means of the shaving step, the method presents the advantage of overcoming the dimensional imprecision that results from applying the liquid composition and then transforming the precursor. It is very difficult, when producing a deposit by applying a liquid composition (deposition by the liquid method), to obtain a deposit that is regular, which leads to a varying amount of extra thickness relative to the initial size of the composite material part. By returning to said initial size before the chemical vapor infiltration step, which step can easily be mastered to obtain a uniform deposit, the method in accordance with the invention makes it possible not only to achieve leakproofing, but also to solve the problem of controlling dimensions. The deposit produced by the liquid method thus serves to reduce the porosity of the composite material and to fill in surface irregularities, in particular by occupying macropores or setbacks in the vicinity of the surface. It does not lead to a relatively large extra thickness over the entire surface of the composite material, so the subsequent deposit made by chemical vapor infiltration can be anchored down to the pores in the composite material, and can thus be held securely.

The part is preferably shaved after cross-linking the ceramic precursor, and even after it has been transformed into ceramic by heat treatment.

In a variant, the shaving may be performed after the liquid composition has been applied and before the ceramic precursor polymer has been cross-linked.

The method of the invention is more particularly applicable to treating the surfaces of parts made of ceramic matrix composite material, in particular of C/SiC or SiC/SiC composite material.

The composition of the liquid preferably includes a polymer solvent of the ceramic precursor, with the quantity of solvent being selected in particular for adjusting the viscosity of the composition.

The liquid composition may be applied by means of a brush or by some other method, e.g. a spray gun. It may be applied as a plurality of successive layers. After each layer, the ceramic precursor polymer can be subjected to intermediate cross-linking, and the cross-linked polymer may optionally be transformed into ceramic.

The ceramic material obtained by the liquid method may be SiC, with the ceramic precursor polymer then being selected from PCS and PTCS which are SiC precursors, or even from silicones. Other ceramic materials can be obtained by the liquid method, such as silicon nitride Si₃N₄ using polysilazane pyrolized under ammonia gas, or boron nitride BN from polyborazine.

The solid filler may comprise a refractory powder, in particular a powder of a ceramic such as a carbide powder (in particular SiC), a nitride powder, or a boride powder. The grain size of the powder is selected in such a manner that the grains have a mean dimension that is preferably less than 100 micrometers (μm), e.g. lies in the range 5 μm to 50 μm.

The grain size is selected in such a manner that the powder grains are small enough to be capable of penetrating into the surface pores of the composite material, but nevertheless not too small, so as to avoid plugging said pores in such a manner that the diffusion of gas within the pores is hindered or even prevented during the subsequent step of chemical vapor infiltration. As a result, the coating formed during said subsequent chemical vapor infiltration step can be securely bonded by being anchored in the pores of the material. According to an advantageous feature of the method, a mixture of ceramic powders is used presenting at least two different mean grain sizes in order to satisfy the above conditions.

The quantity by weight of the solid filler in the liquid composition preferably lies in the range 0.4 times to 4 times the quantity by weight of the ceramic precursor polymer.

When it is desired to treat the entire surface of a part, in particular in order to make it completely leakproof, it is possible to proceed with the following operations for the chemical vapor infiltration step:
placing the part on one or more supports each provided with a separation layer of material weaker than the ceramic material obtained by chemical vapor infiltration, the separation layer being surmounted by a continuity layer made out of said ceramic material;
performing the chemical vapor infiltration; and
separating the parts from the support(s) by breakage within the separation layer, continuity of the ceramic deposit in the vicinity of the or each support zone being provided by the ceramic material of the continuity layer that remains in place on the part.

The separation layer may be a material having a laminated structure, with the support and the part being separated by cleavage within the material of laminated structure. This material may be selected from pyrolytic carbon of laminar type, boron nitride of hexagonal structure, laminated graphite, or silico-aluminous materials of lamellar structure such as talcs and clays.

The ceramic deposit formed by chemical vapor infiltration may be made of a material selected from SiC, Si₃N₄, or alumina Al₂O₃, for example.

The invention also seeks to provide a method of brazing parts made of thermostructural composite material.

This object is achieved by a brazing method in which a method as defined above is used for treating at least those surfaces of the parts that are to be assembled together prior to interposing brazing material between said surfaces and performing brazing.

The surface treatment previously performed on the parts enables them to be given the dimensional precision required for good bonding by brazing, and also serves to achieve a desirable level of leakproofing to prevent the brazing material flowing into the pores of the composite material. The quantity of brazing material can then be accurately adjusted as a function of requirements.

### BRIEF DESCRIPTION OF THE DRAWINGS

The invention can be better understood on reading the following description given by way of non-limiting indication. Reference is made to the accompanying drawings, in which:

FIG. 1 is a flow chart showing the successive steps of an implementation of the method in accordance with the invention;

FIGS. 2 to 4 are diagrams showing the implementation of the method at the surface of a part made of thermo-structural composite material;

FIGS. 5 and 6 are flow charts showing the successive steps of variant implementations of a method in accordance with the invention;

FIG. 7 shows an application of the method of the invention to brazing parts that have been leakproofed;

FIG. 8 is a detail view at the contact between a part and a support in a first particular implementation of the method;

FIG. 9 is a view analogous to that of FIG. 8 after a ceramic deposit has been formed by chemical vapor infiltration;

FIG. 10 is a view analogous to FIG. 9 after the part and the support has been separated; and

FIG. 11 is a scanning electron micrograph showing a portion of the surface of a sample of thermostructural composite material treated in accordance with the invention.

### DETAILED DESCRIPTION OF AN IMPLEMENTATION

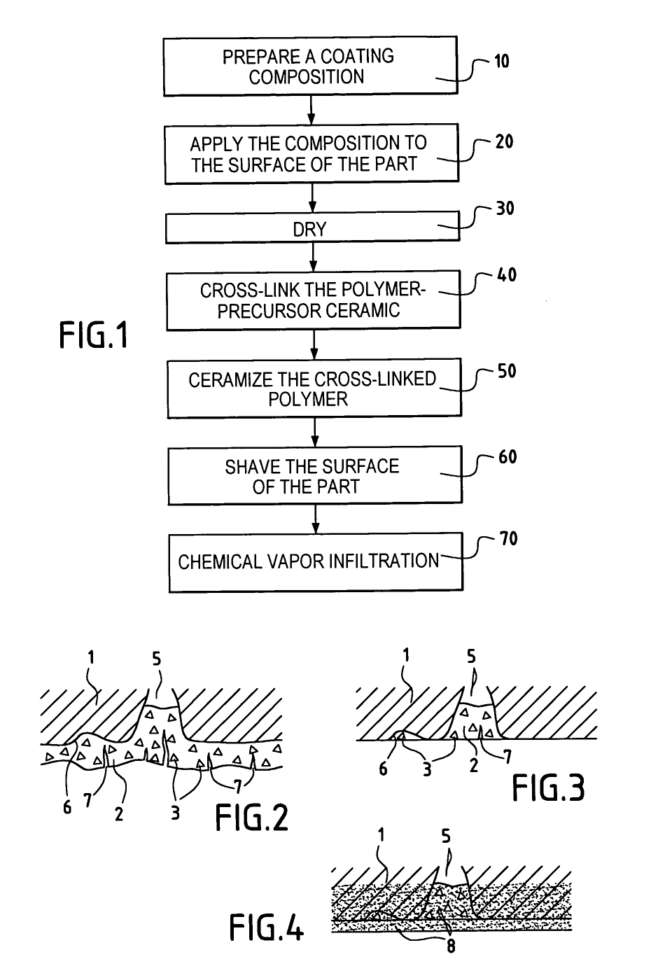

With reference to FIG. 1, an implementation of a method in accordance with the invention for treating the surface of a part made of thermostructural composite material comprises the following steps.

A coating composition is prepared (step 10) which comprises a ceramic precursor polymer containing a filler of refractory solid in the form of a powder, in particular a ceramic, and optionally a solvent for the polymer.

By way of example, the powder is an SiC powder. Its grain size is selected to be fine enough to enable the grains of powder to penetrate into the surface pores in order to fill in the thermostructural composite material. Nevertheless, the grain size is not too fine, in order to avoid clogging the surface pores to such an extent that gas diffusion into the pores of the composite material is impeded during a subsequent step of chemical vapor infiltration. As a result, the coating formed during said subsequent step of chemical vapor infiltration can be securely bonded by being anchored in the pores of the material. The mean size of the grains is thus preferably selected to be smaller than 100 μm, i.e. to lie in the range 5 μm to 50 μm. It is possible to use powders having different grain sizes, the smaller grains contributing to achieving good reduction of the surface pores while the larger grains contribute to leaving room for gas to diffuse. For example, it is possible to use grains having a mean size lying in the range 5 μm to 15 μm in association with grains having a mean size lying in the range 25 μm to 50 μm, with the proportion by weight of the grains having the larger mean size being, for example, not less than the proportion by weight of the grains having the smaller mean grain size.

Other powders, in particular ceramic powders, can be used, with substantially the same grain sizes, e.g. powders selected from carbide powders (other than SiC), nitride powders, or boride powders, it being possible to mix together powders of different kinds.

When the thermostructural material is a C/C composite, the use of a powder having a coefficient of expansion that is smaller than SiC, e.g. Si₃N₄ powder, can be envisaged in order to adapt to the underlying material and limit any risk of cracking.

The ceramic precursor polymer is selected as a function of the nature of the desired coating. When an SiC coating is desired, the polymer is selected, for example, from polycarobosilane (PCS) and polytitanocarbosilane (PTCS).

Other ceramic precursor polymers can be used, for example silicones which are SiC precursors (or precursors of SIC+C when they have excess carbon), polysilazanes which, when pyrolyzed under ammonia gas, serve to obtain Si₃N₄, and polyborazines, which are precursors for BN.

It should be observed that the ceramic constituting the solid filler and the ceramic for which the polymer is a precursor are preferably, but not necessarily, of the same kind.

The solvent is determined as a function of the ceramic precursor polymer that is used. For example, when using PCS, the solvent may be xylene. Other solvents are suitable for use with other polymers, e.g. heptane, hexane, or ethanol for silicones.

The quantity of solid filler relative to the quantity of ceramic precursor polymer is selected to ensure satisfactory filling of the surface pores of the thermostructural composite material, while still allowing the composition to penetrate to a certain depth. Thus, the quantity by weight of the solid filler preferably lies in the range 0.4 times to 4 times the quantity by weight of the ceramic precursor polymer.

The quantity of solvent used is selected to confer the appropriate viscosity to the liquid composition to enable it to be applied to the surface of the part.

By way of example, a typical composition for a composition that is to form an SiC coating can be selected from within the following limits:
SiC powder (mean grain size in the range 5 μm to 50 μm): 2 to 7 parts by weight;
PCS (SiC precursor): 1 to 3 parts by weight;
xylene (PCS solvent): 2 to 5 parts by weight.

The liquid composition is applied to the surface of the part that is to be treated (step 20).

Application may be performed simply by means of a brush. Other methods can be used, e.g. a spray gun.

After drying (step 30), e.g. in hot air, for the purpose of eliminating the solvent, the ceramic precursor polymer is cross-linked (step 40). Cross-linking may be performed by heat treatment. Under such circumstances, when using PCS, for example, the temperature is raised progressively up to a level at about 350° C.

The cross-linked polymer is subjected to heat treatment in order to convert it into a ceramic (ceramization) (step 50). When using PCS, transformation into SiC is implemented by raising the temperature progressively up to a level of about 900° C.

A plurality of successive layers of liquid composition can be applied. After each layer has been applied, the composition is preferably at least dried and the ceramic precursor polymer cross-linked. Ceramization may be performed simultaneously for all of the layers.

Naturally, the cross-linking and ceramization conditions may be different when using other ceramic precursors, such conditions not presenting any original character.

As shown very diagrammatically in FIG. 2, this produces a ceramic coating comprising a phase 2 obtained by ceramizing the ceramic precursor together with a solid filler 3. The coating simultaneously fills in surface recesses such as the recess 6 and open macropores in the material of the part 1, such as the macropore 5, down to a certain depth from the surface of the part. The coating also covers the initial surface of the part 1. Cracks 7 may be present in the coating.

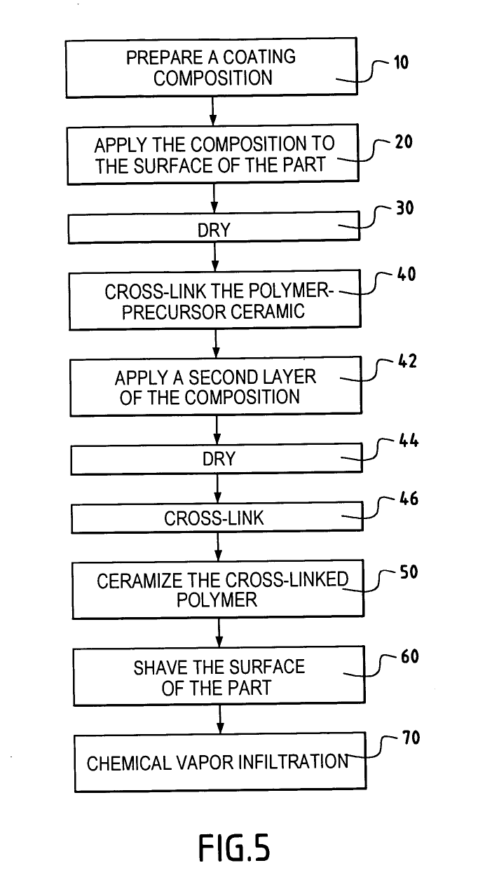

After ceramization, the surface of the part is shaved (step 60) to return it to its initial shape, i.e. to the envelope of its initial outside surface, as shown in FIG. 3. Shaving may be achieved by abrasive polishing since the ceramization residue of the ceramic precursor polymer together with the solid filler is friable.

The part still presents residual porosity in the vicinity of its surface, but its initial porosity has been modified by the micropores being filled at least in part and by the macropores being subdivided. In addition, surface irregularities have been filled in.

After shaving, ceramic is deposited by chemical vapor infiltration (step 70). This deposit serves to fill in the residual pores, to consolidate the assembly formed by the phase derived from ceramizing the precursor and the solid filler, and to form a uniform ceramic coating which leakproofs the surface of the part, as shown in FIG. 4 where reference 8 designates the ceramic formed by chemical vapor infiltration.

Because the initial roughness of the part has been compensated to a large extent, it is possible to obtain a coating of smooth appearance without requiring the coating to be of great thickness. The thickness of the coating is preferably less than 200 μm, e.g. lying in the range 25 μm to 150 μm. In addition, the chemical vapor infiltration process makes it possible to obtain a deposit of uniform and controllable thickness, thus making it possible to master accurately the final dimensions of the part. Final dimensions can be adjusted, e.g. by polishing, where such polishing can give a mirror appearance to the surface of the part. It should also be observed that the deposit obtained by chemical vapor infiltration becomes anchored not only in the deposit obtained using the liquid method, but also in the pores of the composite material. The presence of the solid filler and of the cracks 7 contributes to the reaction gas diffusing.

The natures of the reaction gases and the temperature and pressure conditions needed for obtaining a variety of ceramic deposits by chemical vapor infiltration are themselves well known.

When depositing SiC, and is known in itself, it is possible to use a gas containing methyltrichorosilane (MTS) as the SiC precursor and hydrogen gas (H₂) acting as a vector gas for contributing to diffusion within the pores of the part.

FIG. 5 relates to a variant implementation of the method which differs from that of FIG. 1 in that the liquid composition is applied in two successive layers. Thus, after cross-linking step 40, and prior to ceramization step 50, a series of steps are performed comprising a step 42 in which the composition is applied a second time, a step 44 in which it is dried, and a step 46 in which it is cross-linked.

It is preferable to cross-link the ceramic precursor polymer before applying the second layer in order to avoid dissolving the preceding layer while applying the second layer, but this is not essential.

It is also possible to apply the second layer after ceramizing the first. Naturally, more than two layers could be applied.

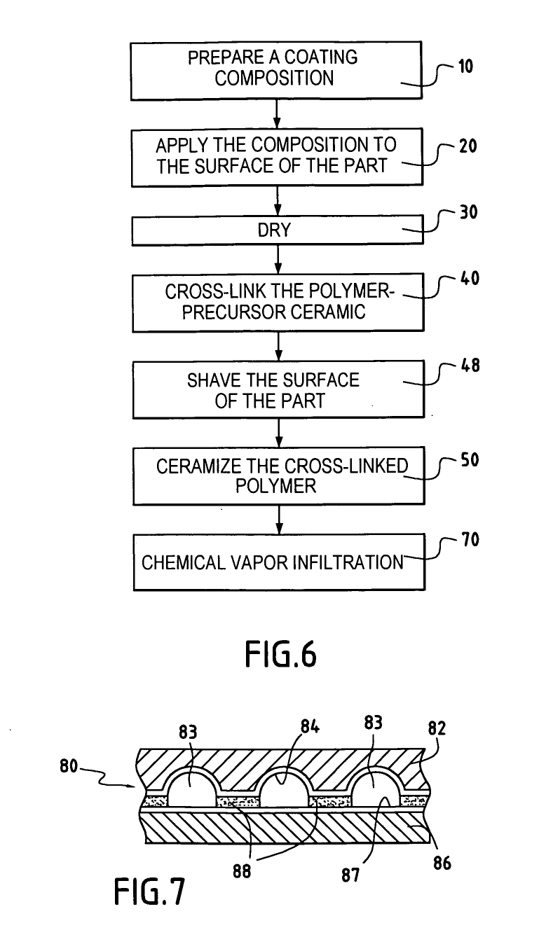

FIG. 6 relates to another variant implementation of the method which differs from that of FIG. 1 in that the shaving step 48 is performed after the cross-linking step 40 and before ceramization, with step 60 then being omitted. It is also possible to envisage performing the shaving step after the composition drying step 30.

An application mentioned above of the method lies in making parts having a surface that presents a mirror appearance. Such parts are typically made of CMCs such as C/SiC or SiC/SiC, with the surface being treated by forming an SiC coating by the liquid method, shaving, and depositing SiC by chemical vapor infiltration.

Another application lies in making parts out of thermo-structural composite material having at least a portion of their surface that has been leakproofed.

Yet another application lies in making parts of dimensions that are accurately controlled in order to be suitable for bonding to other parts by brazing.

FIG. 7 shows an example of a structure being made by combining the two last-mentioned applications, specifically a wall structure for a thruster nozzle diverging portion that is cooled by circulating a fluid.

This structure 80 is formed by two parts 82 and 86 made of CMC, e.g. of SiC/SiC. One of the parts (82) has a surface in which grooves or recesses 83 are formed in order to constitute circulation channels for a fluid for cooling the structure. The surface of the part 82 in which the channels 83 are formed is treated in accordance with the invention in order to form a leakproofing coating 84 of controlled thickness, e.g. a coating of SiC. The other part 86 also has a surface treated in accordance with the invention in order to form a leakproofing coating 84 of controlled thickness and of the same kind as the coating 84 (the thicknesses of the coatings 84 and 87 are exaggerated in FIG. 7). The two treated surfaces are placed one against the other with a layer of brazing material 88 being interposed between them, and the parts are brazed together by raising the temperature. With the coatings 84 and 87 made of SiC, it is possible to use a brazing material based on silicon, as described in French patent applications Nos. 2 748 471 or 2 748 787.

The treatment method in accordance with the invention contributes to preparing parts for brazing in that by controlling the shapes of the parts it makes it possible to obtain the desired degree of precision for docking together the surfaces that are to be assembled, and in that the brazing material is prevented from flowing into the pores of the thermostructural composite material by leakproofing the surfaces that are to be assembled together. The quantity of brazing material can thus easily be controlled.

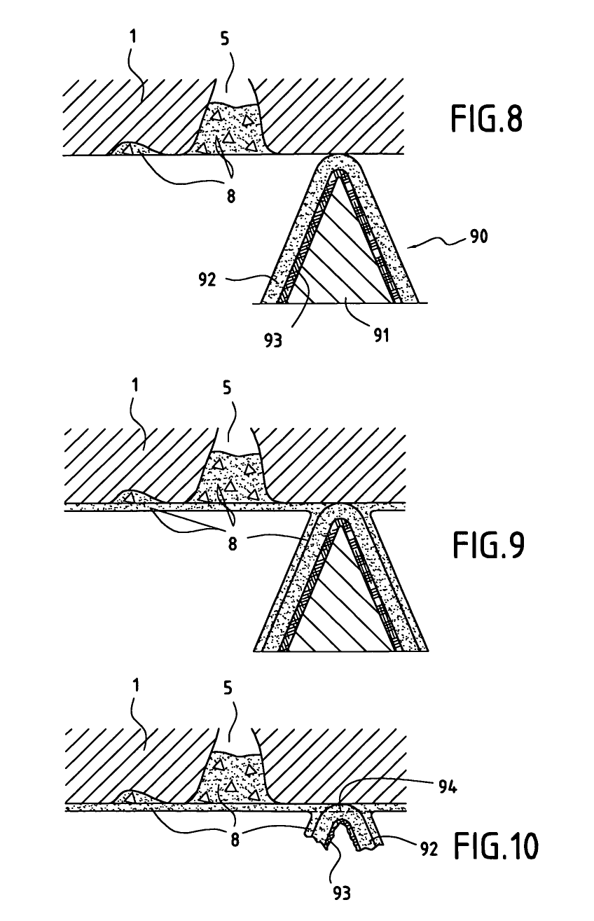

FIGS. 8 to 10 show a variant implementation of the method of the invention when a ceramic deposit is to be formed by chemical vapor infiltration over the entire surface of the shaved part.

The part 1, in the state shown in FIG. 3, is put into place on one or more supports 90. Each support is cone- or pyramid-shaped so as to present at its tip a contact zone with the part 1 that is of limited area. Supports of other shapes can be envisaged, for example prism-shaped bars presenting a limited contact area along an edge.

Each support 90 comprises a substrate 91 of refractory material, e.g. graphite, or of thermostructural composite material such as a C/C composite material, and an outer layer 92 made of the same ceramic material as the deposit that is to be made on the part 1 by chemical vapor infiltration. The layer 92 for constituting a continuity layer in the ceramic deposit that is to be made. A separation layer 93 of refractory material that is weaker than the ceramic of the layer 92 is interposed between the substrate 91 and the layer 92.

The separation layer 93 defines a zone of weakness. It is advantageously made of a material that is of lamellar structure, or a material that is cleavable, such as laminar type pyrolytic carbon (PyC), hexagonal boron nitride (BN), laminated graphite, or any other refractory material such as lamellar silico-aluminates, such as talcs or clays.

The PyC or BN layer can be obtained by chemical vapor infiltration or by deposition. Reference can be made to document EP 0 172 082 which describes making a PyC or BN lamellar inter-phase presenting low shear strength between the fibers and a matrix of a thermostructural composite material having refractory reinforcing fibers and a ceramic matrix.

A layer of BN or of laminated graphite may also be obtained by spraying, optionally followed by smoothing using a known technique that is used in particular for forming a layer of unmolding agent on the wall of a mold, e.g. using the BN-based product sold under the name “Pulvé Aéro A” by the French supplier “Acheson France”.

The layer of talc or clay may also be obtained by spraying in finely divided form followed by smoothing.

The thickness of the layer 93 must be sufficient subsequently to enable separation to take place by rupture occurring within this layer, without damaging the ceramic layer 92.

Nevertheless, this thickness must remain relatively small so as to ensure sufficient bonding for the outer layer 92 until final separation takes place.

The thickness of the layer 93 is preferably selected to lie in the range 0.1 μm to 20 μm, typically lying in the range 0.5 μm to 5 μm.

The ceramic layer 92 is made by deposition or by chemical vapor infiltration. Its thickness is selected to be at least equal to the thickness of the deposit that is to be formed on the part 1.

After being loaded into an oven, the ceramic deposit 8 is formed on the part 1 and also on the exposed lateral faces of the support(s) 90, as shown in FIG. 9.

After the deposit 8 has been formed, the part 1 is removed from the oven together with the support(s) 90, and then the or each support 90 is physically separated from the part 1. Because of the presence of the layer of weakness 93, separation between the support and the part takes place within said layer 93, as shown in FIG. 10.

Continuity of the ceramic deposit on the part is ensured in the contact zone with a support by the layer 92 of the support that remains attached to the part 1. The excess fraction of the layer 92 may subsequently optionally be eliminated by machining (see continuous line 94 in FIG. 10) so that a continuous ceramic deposit of substantially constant thickness is formed over the entire surface of the part 1.

In order to ensure good bonding between the layer 92 and the deposit 8, the layer 92 is preferably made by a chemical vapor infiltration process similar to that used for making the deposit 8, so as to obtain deposits having the same structure. In addition, prior to making the deposit 8, surface treatment may be performed on the surface of the outer layer 92 so as to clear it of any impurities and/or a silica film (SiO₂) that might have formed thereon, so as to facilitate strong binding with the deposit 8.

One such surface treatment may consist in heat treatment, e.g. at a temperature lying in the range 1200° C. to 1900° C. under a secondary vacuum. A silica film is eliminated by reacting with SiC, i.e.:
SiC+2SiO2→3SiO+CO

In a variant, the surface treatment is acid attack, e.g. using hydrofluoric acid (HF) also for eliminating the surface film of SiO₂.

### EXAMPLES

Two layers of a composition comprising polycarbosilane (PCS) diluted in xylene and having a solid filler in the form of ceramic powders were applied to one of the surfaces of samples of a C/SiC thermostructural composite material, and the powder composition was varied as set out in the table below. On each occasion, after the first layer had been applied, it was dried in air to eliminate the xylene and the PCS was cross-linked by raising its temperature up to about 350° C., and after the second layer had been applied, the same drying and cross-linking steps were performed followed by a step of ceramizing all of the cross-linked PCS by raisin the temperature up to about 900° C.

On each occasion, the ratio by weight of PCS and xylene was equal to about ⅔, while the ratio by weight of solid filler to PCS was equal to about 1.

TABLE

| | Powders used | | Weight ratio |
|---|---|---|---|
| | Powder 1 | Powder 2 | Powder 1/ |
| Sample | (mean grain size) | (mean grain size) | powder 2 |
| 1 | SiC (37 μm) | SiC (9 μm) | 2.3 |
| 2 | SiC (37 μm) | HfB₂ (35 μm) | 1.4 |
| 3 | SiC (37 μm) | ZrB₂ (35 μm) | 0.8 |

After ceramization, the surfaces of the samples were shaved by polishing with abrasive paper and SiC was deposited by chemical vapor infiltration with a reaction gas containing a mixture of MTS and H₂. The chemical vapor infiltration was continued until the film thickness of the resulting SiC surface coating was equal to about 50 μm.

A tear-off traction test was performed on the SiC coatings formed on the surfaces of the samples. In all three cases, and for a breaking stress of about 20 megapascals (MPa), it was found that breaking took place within the composite material, confirming the excellent anchoring of the coating to the surface of the material.

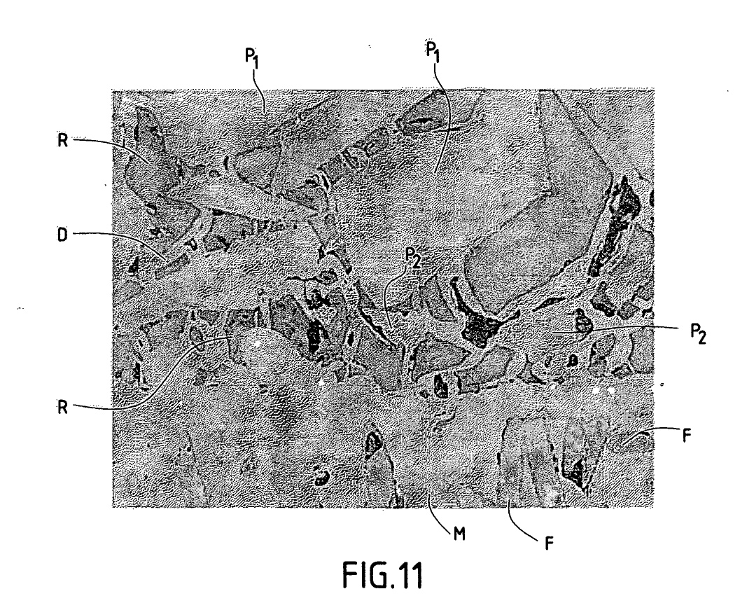

This anchoring can be visualized in the micrograph of FIG. 11 which shows a portion of the surface of sample 1 after surface treatment. In this figure, there can be seen the fibers F, the SiC matrix M of the thermostructural composite material, the powders P₁ and P₂ of different grain sizes, the residue R of SiC coming from ceramizing the PCS, and the deposit D of SiC obtained by chemical vapor infiltration.

It can be seen that the assembly formed by the ceramization residue R and the powders P₁ and P₂ does indeed fill in the surface pores of the material. It can also be seen that the deposit D is formed not only the surface but also on the walls of the micropores in the material (see arrows f).

1. A method of treating the surface of a part made of thermostructural composite material possessing a surface that is porous and of rough appearance, the method comprising applying onto the surface of the part a liquid composition containing a ceramic precursor polymer and a refractory solid filler, cross-linking the polymer, transforming the cross-linked polymer into ceramic by heat treatment, and subsequently forming a ceramic deposit by chemical vapor infiltration, the method being characterized in that prior to the step of chemical vapor infiltration, the surface of the part is shaved to return the part made of composite material to its initial shape so that the chemical vapor infiltration forms a deposit that fills in the residual micropores in the shaved surface of the part.

2. A method according to claim 1, characterized in that the shaving is performed after the precursor polymer has been cross-linked.

3. A method according to claim 2, characterized in that the shaving is performed after the precursor polymer has been ceramized by heat treatment.

4. A method according to claim 1, characterized in that the shaving is performed after the liquid composition has been applied and before the ceramic precursor has been cross-linked.

5. A method according to claim 1, characterized in that the liquid composition comprises a solvent for the ceramic precursor polymer.

6. A method according to claim 1, characterized in that the liquid composition is applied in a plurality of layers.

7. A method according to claim 1, characterized in that the solid filler comprises at least one refractory powder of mean grain size smaller than 100 μm.

8. A method according to claim 7, characterized in that the mean grain size of the powder lies in the range 5 μm to 50 μm.

9. A method according to claim 1, characterized in that the solid filler comprises at least two powders of different mean grain sizes.

10. A method according to claim 1, characterized in that, for the chemical vapor infiltration step, the following operations are performed:
placing the part on one or more supports each provided with a separation layer of material weaker than the ceramic material obtained by chemical vapor infiltration, the separation layer being surmounted by a continuity layer made out of said ceramic material;
performing the chemical vapor infiltration; and
separating the parts from the support(s) by breakage within the separation layer, continuity of the ceramic deposit in the vicinity of the or each support zone being provided by the ceramic material of the continuity layer that remains in place on the part.

11. A method according to claim 10, characterized in that the separation layer is made of a material of laminated structure.

12. A method according to claim 1, characterized in that the deposit formed by chemical vapor infiltration is silicon carbide.

13. A method according to claim 1, characterized in that the surface of the part is polished after the chemical vapor infiltration step.

14. A method of brazing together two parts of thermostructural composite material, the method being characterized in that the surfaces of the parts that are to be assembled together are subjected to treatment by a method in accordance with claim 1, and the brazing is performed after interposing brazing material between the treated surfaces.

15. A method according to claim 3, characterized in that:
the liquid composition comprises a solvent for the ceramic precursor polymer;
the liquid composition is applied in a plurality of layers;
the solid filler comprises at least one refractory powder of mean grain size smaller than 100 μm;
the mean grain size of the powder lies in the range 5 μm to 50 μm;
the solid filler comprises at least two powders of different mean grain sizes;
for the chemical vapor infiltration step, the following operations are performed:
placing the part on one or more supports each provided with a separation layer of material weaker than the ceramic material obtained by chemical vapor infiltration, the separation layer being surmounted by a continuity layer made out of said ceramic material;
performing the chemical vapor infiltration; and
separating the parts from the support(s) by breakage within the separation layer, continuity of the ceramic deposit in the vicinity of the or each support zone being provided by the ceramic material of the continuity layer that remains in place on the part;
the separation layer is made of a material of laminated structure;
the deposit formed by chemical vapor infiltration is silicon carbide;
the surface of the part is polished after the chemical vapor infiltration step.

16. A method according to claim 4, characterized in that:
the liquid composition comprises a solvent for the ceramic precursor polymer;
the liquid composition is applied in a plurality of layers;
the solid filler comprises at least one refractory powder of mean grain size smaller than 100 μm;
the mean grain size of the powder lies in the range 5 μm to 50 μm;
the solid filler comprises at least two powders of different mean grain sizes;
for the chemical vapor infiltration step, the following operations are performed:
placing the part on one or more supports each provided with a separation layer of material weaker than the ceramic material obtained by chemical vapor infiltration, the separation layer being surmounted by a continuity layer made out of said ceramic material;
performing the chemical vapor infiltration; and
separating the parts from the support(s) by breakage within the separation layer, continuity of the ceramic deposit in the vicinity of the or each support zone being provided by the ceramic material of the continuity layer that remains in place on the part;
the separation layer is made of a material of laminated structure;
the deposit formed by chemical vapor infiltration is silicon carbide;
the surface of the part is polished after the chemical vapor infiltration step.

17. A method of brazing together two parts of thermo-structural composite material, the method being characterized in that the surfaces of the parts that are to be assembled together are subjected to treatment by a method in accordance with claim 15, and the brazing is performed after interposing brazing material between the treated surfaces.

18. A method of brazing together two parts of thermo-structural composite material, the method being characterized in that the surfaces of the parts that are to be assembled together are subjected to treatment by a method in accordance with claim 16, and the brazing is performed after interposing brazing material between the treated surfaces.
